(19) United States
(12) Patent Application Publication
(10) Pub. No.: US 2017/0025589 A1
(43) Pub. Date: Jan. 26, 2017

(54) LIGHT EMITTING STRUCTURE AND METHOD FOR MANUFACTURING THE SAME

(71) Applicant: EPISTAR CORPORATION, Hsinchu (TW)

(72) Inventors: Chun-Chih Chang, Hsinchu (TW); Shang-Yu Tsai, Hsinchu (TW); Hao-Yu Yang, Hsinchu (TW); Ching-Hui Chen, Hsinchu (TW); Jung-Tang Chu, Hsinchu (TW); Yu-Sheng Tang, Hsinchu (TW)

(21) Appl. No.: 14/806,283

(22) Filed: Jul. 22, 2015

(51) Int. Cl. H01L 33/56; H01L 33/62; H01L 25/075; H01L 33/50; H01L 33/58

(52) U.S. Cl. CPC H01L 33/56; H01L 33/507; H01L 33/58; H01L 25/0753; H01L 33/62; H01L 2933/0091; H01L 2933/0041; H01L 2933/005; H01L 2933/0058; H01L 2933/0066

(57) ABSTRACT

The present disclosure provide a light emitting device package, including a light emitting die emitting a first color and an encapsulant encapsulating the light emitting die. The encapsulant includes a matrix and a plurality of inert particles dispersed in the matrix. The inert particles are transparent to the first color, and a radiation pattern of the light emitting package is lambertian-like.

### BACKGROUND

LED devices are semiconductor photonic devices that emit light when a voltage is applied. LED devices have increasingly gained popularity due to favorable characteristics such as small device size, long lifetime, efficient energy consumption, and good durability and reliability. In recent years, LED devices have been deployed in various applications, including indicators, light sensors, traffic lights, broadband data transmission, back light unit for LCD displays, and illumination apparatuses. For example, LED devices are often used in illumination apparatuses provided to replace conventional incandescent light bulbs, such as those used in a typical lamp.

Several of the performance criteria for LED illumination apparatuses are high output intensity and with desired illumination pattern. For example, it is intended that the output intensity for an LED illumination apparatus maintain relatively high and illumination pattern maintain uniform and Lambertian-like in narrow light beam applications. Therefore, although existing LED illumination devices are generally adequate for their intended purposes, they have not been entirely satisfactory in every aspect. An LED illumination apparatus having good light output intensity and desired illumination pattern continues to be sought.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A and FIG. 1B show a cross sectional view of light emitting device packages or light emitting apparatus, in accordance with some embodiments of the present disclosure.

FIG. 2 shows a light emission spectrum of light emitting device packages or a light emitting apparatus, in accordance with some embodiments of the present disclosure.

FIG. 3 shows an illumination pattern of a light emitting device package or light emitting apparatus in accordance with some embodiments of the present disclosure, and an illumination pattern of a light emitting device package or a light emitting apparatus without inert particles.

FIG. 4 shows a cross sectional view of a light emitting device package or a light emitting apparatus, in accordance with some embodiments of the present disclosure.

FIG. 5 shows a cross sectional view of a light emitting device package or a light emitting apparatus, in accordance with some embodiments of the present disclosure.

FIG. 6 shows a cross sectional view of a light emitting device package or a light emitting apparatus, in accordance with some embodiments of the present disclosure.

FIG. 7 shows a cross sectional view of a light emitting device package or a light emitting apparatus, in accordance with some embodiments of the present disclosure.

FIG. 8A and FIG. 8B show a cross sectional view of light emitting device packages or light emitting apparatus, in accordance with some embodiments of the present disclosure.

FIG. 9A shows a top view of a light emitting device array package, in accordance with some embodiments of the present disclosure.

FIG. 9B shows a perspective view of the light emitting device array package in FIG. 9A, in accordance with some embodiments of the present disclosure.

FIG. 10A shows a top view of a light emitting device array package, in accordance with some embodiments of the present disclosure.

FIG. 10B shows a perspective view of the light emitting device array package in FIG. 10A, in accordance with some embodiments of the present disclosure.

FIG. 11A shows a top view of a light emitting device array package, in accordance with some embodiments of the present disclosure.

FIG. 11B shows a perspective view of the light emitting device array package in FIG. 11A, in accordance with some embodiments of the present disclosure.

FIG. 12A shows a top view of a light emitting device array package, in accordance with some embodiments of the present disclosure.

FIG. 12B shows a perspective view of the light emitting device array package in FIG. 12A, in accordance with some embodiments of the present disclosure.

FIG. 13 shows a cross sectional view of a light emitting device package or a light emitting apparatus, in accordance with some embodiments of the present disclosure.

FIG. 14 shows a cross sectional view of a light emitting device package or a light emitting apparatus, in accordance with some embodiments of the present disclosure.

FIG. 15 shows a cross sectional view of a light emitting device package or a light emitting apparatus, in accordance with some embodiments of the present disclosure.

FIG. 16 shows operations of a method for manufacturing a light emitting device or a light emitting apparatus, in accordance with some embodiments of the present disclosure.

FIG. 17, FIG. 18, FIGS. 19A-19B, FIGS. 20A-20B show cross sectional views of fragmental operations of the method for manufacturing a light emitting device or a light emitting apparatus, in accordance with some embodiments of the present disclosure.

FIGS. 21A and 21B show applications for the light emitting device or the light emitting apparatus, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The “Lambertian-like” described herein refers to that the relative luminous intensity essentially demonstrating the form of cosine θ where θ is the angle from the defined propagation for the peak intensity of a light emission device.

The “Beam Angle” described herein refers to a key consideration in working with light beams of the light emission device is defining the width of the beam. For IESNA/ANSI/NEMA definitions for Type B distributions the “Beam Angle” is defined as 50% of maximum luminous intensity. These angles refer typically to a half angle.

The “Light Angle” described herein refers to a full angle as 50% of maximum luminous intensity, that is, two times the “Beam Angle”.

The “material being transparent to a certain color” described herein refers to that the absorption peak of the material is not overlapped with the full-width half-maximum (FWHM) of the emission peak of a light emitting device emitting said certain color.

The “inert particle” described herein refers to particles that is chemically inert to the emission light. The inert particle is to be differentiated from the phosphorescent materials and/or fluorescent materials that are devised to interact with the emission light.

Generally, the narrower the light emitting device beam angle, the further the emitted light may travel before losing its intensity. One skilled in the art would understand that the light emitting device beam angle is a design parameter that is based upon the particular application. Under certain applications, the light emitting device beam angle may nonetheless be too wide for use in a lighting fixture. For example, flip chip light emitting diode (LED) package possess greater light angle than the vertical chip LED package, and hence limiting the flip chip LED package from flash light applications.

To obtain 120 degrees light angle output with uniform radiation pattern, current light emitting device or apparatus relies on secondary optics such as computer-designed lenses or multi-faceted/parabolic reflectors to collimate and to shape the light emitted from a dome or phosphor-coated light emitting device into desired beam angle. In addition, current light emitting device deploys colored diffusers such as TiOₓ, ZrOₓ to enhance scattering effect in pursuit of radiation uniformity. The aforesaid approaches suffer efficiency losses due to the absorption loss contributed by colored particles and coupling loss of a lens to a dome. For example, the coupling of a lens to a dome causes efficiency losses of approximately 15%.

Present disclosure provides a light emitting device package having a light emitting die emitting a first color, and an encapsulant surrounding the light emitting die. The encapsulant includes binding agents and a plurality of inert particles dispersed in the binding agents or a matrix. The inert particles are transparent to the first color such that no absorption loss may occur, and a radiation pattern of the light emitting package is Lambertian-like due to the scattering between the inert particles. In some embodiments, a flip chip LED package demonstrates 120 degrees view angle, uniform radiation pattern, and good output intensity.

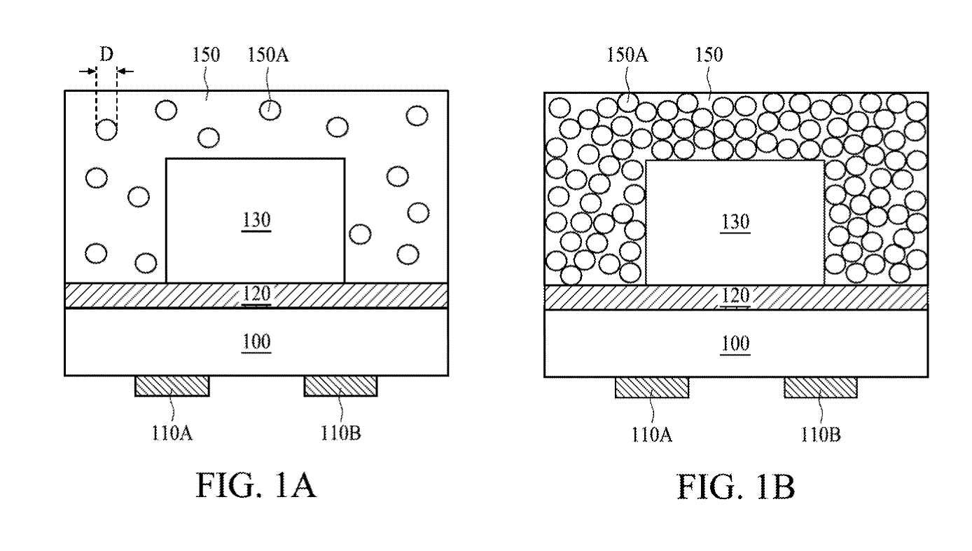

Referring to FIG. 1A, a cross sectional view of light emitting device package or light emitting apparatus is shown. In FIG. 1A, a substrate 100 is provided. The substrate 100 may include a glass substrate, a silicon substrate, a ceramic substrate, a gallium nitride substrate, or any other suitable substrate that can provide mechanical strength and support. The substrate 100 may also be referred to as a carrier substrate. A tape 120 is disposed on the substrate 100. In some embodiments, the tape 120 may contain an adhesive material. A semiconductor light emitting die 130 is disposed over the tape 120 and the substrate 100. In some embodiments, the semiconductor photonic dies 130 are LED dies in the embodiments described below, and as such may be referred to as LED 130 in the following paragraphs

The LED 130 each include two differently doped semiconductor layers formed, or grown, on a growth substrate. The growth substrate may be sapphire, silicon, silicon carbide, gallium nitride, etc., and is included in each of the LED 130 shown herein. The oppositely doped semiconductor layers have different types of conductivity. For example, one of these semiconductor layers contains a material doped with an n-type dopant, while the other one of the two semiconductor layers contains a material doped with a p-type dopant. In some embodiments, the oppositely doped semiconductor layers each contain “III-V” family (or group) compounds. In more detail, III-V family compound contains an element from “III” family of the periodic table, and another element from a “V” family of the periodic table. For example, the III family elements may include Boron, Aluminum, Gallium, Indium, and Titanium, and the V family elements may include Nitrogen, Phosphorous, Arsenic, Antimony, and Bismuth. In certain embodiments, the oppositely doped semiconductor layers include a p-doped gallium nitride (p-GaN) material and an n-doped gallium nitride material (n-GaN), respectively. The p-type dopant may include Magnesium (Mg), and the n-type dopant may include Carbon (C) or Silicon (Si).

The LED 130 also each include a light emitting layer such as a multiple-quantum well (MQW) layer that is disposed in between the oppositely doped layers. The MQW layer includes alternating (or periodic) layers of active material, such as gallium nitride and indium gallium nitride (InGaN). For example, the MQW layer may include a number of gallium nitride layers and a number of indium gallium nitride layers, wherein the gallium nitride layers and the indium gallium nitride layers are formed in an alternating or periodic manner. In some embodiments, the MQW layer includes ten layers of gallium nitride and ten layers of indium gallium nitride, where an indium gallium nitride layer is formed on a gallium nitride layer, and another gallium nitride layer is formed on the indium gallium nitride layer, and so on and so forth. The light emission efficiency depends on the number of layers of alternating layers and thicknesses. In certain alternative embodiments, suitable light-emitting layers other than an MQW layer may be used instead.

Each LED 130 may also include a pre-strained layer and an electron-blocking layer. The pre-strained layer may be doped and may serve to release strain and reduce a Quantum-Confined Stark Effect (QCSE)—describing the effect of an external electric field upon the light absorption spectrum of a quantum well in the MQW layer. The electron blocking layer may include a doped aluminum gallium nitride (AlGaN) material, wherein the dopant may include Magnesium. The electron blocking layer helps confine electron-hole carrier recombination to within the MQW layer, which may improve the quantum efficiency of the MQW layer and reduce radiation in undesired bandwidths.

The n-doped semiconductor layer, the p-doped semiconductor layer, and the MQW disposed in between collectively constitute a core portion of an LED 130. When an electrical voltage (or electrical charge) is applied to the doped layers of the LED 130, the MQW layer emits radiation such as light. The color of the light emitted by the MQW layer corresponds to the wavelength of the radiation. The radiation may be visible, such as blue light, or invisible, such as ultraviolet (UV) light. The wavelength of the light (and hence the color of the light) may be tuned by varying the composition and structure of the materials that make up the MQW layer. For example, the LED die 130 herein may be blue light emitters. In some embodiments, a center wavelength (or peak wavelength) of the LED 130 is tuned to be in a range from about 460 nm to about 490 nm. The light emitted from the LED 130 is referred to the “first color” hereinafter.

As shown in FIG. 1, each LED die 130 also includes two conductive terminals 110A and 110B, which may include metal pads. Electrical connections to the LED die 130 may be established through the conductive terminals 110A/110B. In the embodiments discussed herein, one of the conductive terminals 110A/110B is a p-terminal (i.e., electrically coupled to the p-GaN layer of the LED 130), and the other one of the conductive terminals 110A/110B is an n-terminal (i.e., electrically coupled to the n-GaN layer of the LED 130). Thus, an electrical voltage can be applied across the terminals 110A and 110B to generate a light output from the LED 130.

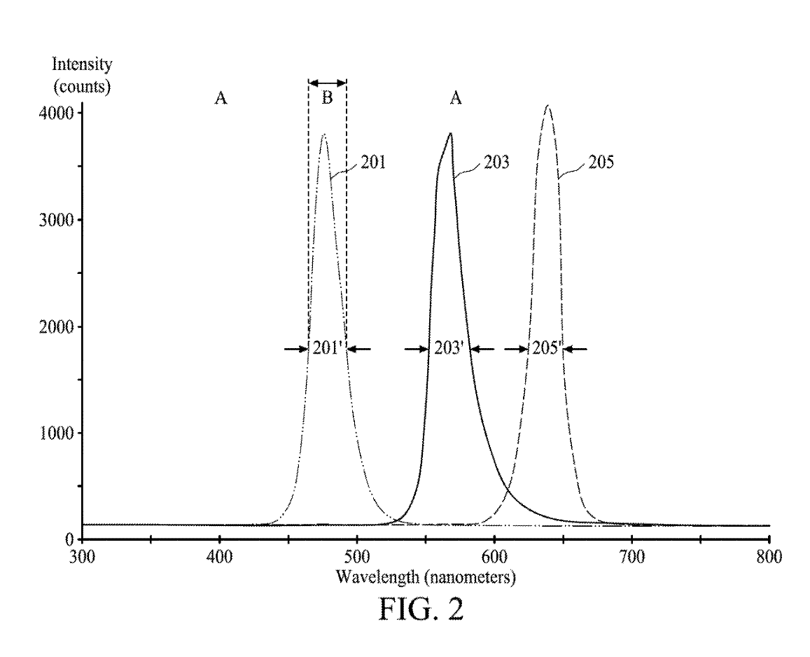

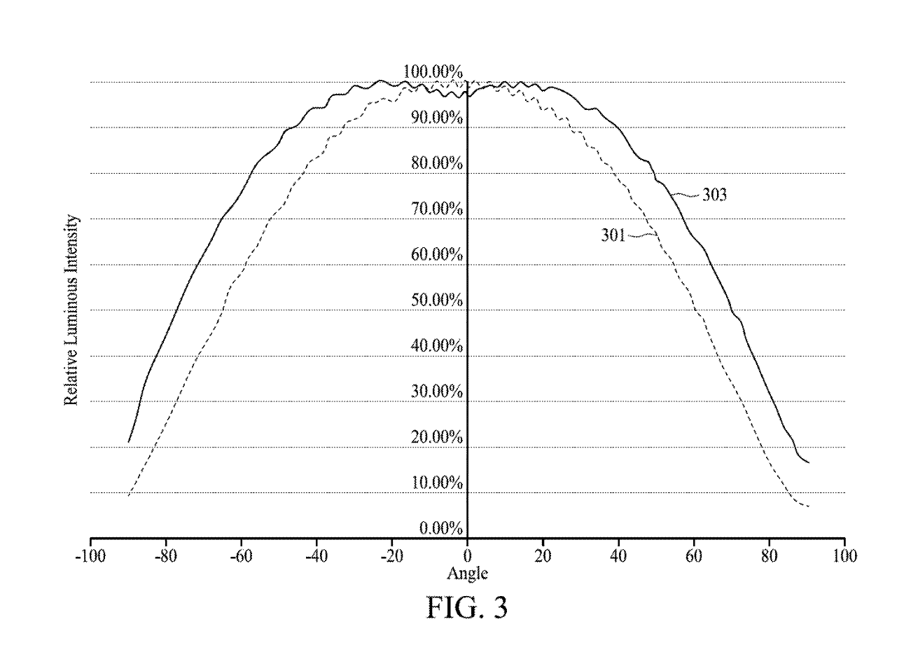

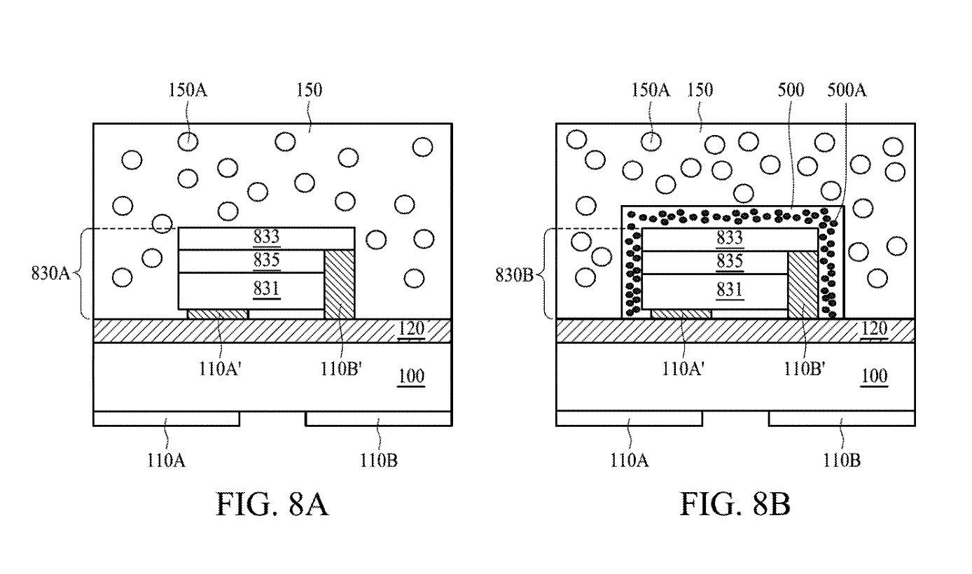

As shown in FIG. 1A and FIG. 1B, an encapsulant (150, 150A) encapsulates the LED 130. In some embodiments, the encapsulant includes binding agent (also referred to as matrix) 150 and inert particles 150A dispersed in the matrix 150. The inert particles 150A are transparent to the first color emitting from the LED 130. More discussion with respect to “transparent to the first color” can be found in FIG. 2 below. The radiation pattern of the light emitting device packages shown in FIG. 1A and FIG. 1B is Lambertian-like. More discussion with respect to “Lambertian-like” radiation pattern can be found in FIG. 3 below. In some embodiments, the LED 130 is packaged in a flip chip fashion as shown in FIG. 8A and FIG. 8B. The loading of the inert particles 150A illustrated in FIG. 1B is greater than that in FIG. 1A. In some embodiments, the matrix 150 occupies greater volume than the inert particles 150A such that each inert particle 150A is dispersed and surrounded by the matrix 150, as shown in FIG. 1A. In other embodiments, the matrix 150 occupies less volume than in the inert particles 150A such that inert particles 150A may contact the adjacent ones and the matrix 150 merely acts as binding agents holding the inert particles 150A together, as shown in FIG. 1B.

Referring to FIG. 2, FIG. 2 shows a light emission spectrum of light emitting device packages or a light emitting apparatus in some of the present embodiments. The first emission peak 201 ranges from about 450 nm to about 500 nm (blue light), the second emission peak 203 ranges from about 500 nm to about 570 nm (green light), the third emission peak 205 ranges from about 610 nm to about 760 nm (red light) may be emitted from three of the LED 130 illustrated in FIG. 1A and FIG. 1B. The full width half maximum (FWHM) of the emission peaks 201, 203, 205 are denoted 201′, 203′, 205′, respectively. The FWHM band width of each emission peak is approximately from about 24 nm to about 27 nm. In the present disclosure, when a material is referred to be “transparent” to the first color emitted from the LED 130, the absorption peak of said materials is not overlapping with the FWHM of said first color emission peak. For example, when the LED 130 emits a blue light showing the emission peak 201, the FWHM of the emission peak 201 spans the B band (about 460 nm to 490 nm), and the rest of the spectrum is categorized in the A band. In some embodiments, the absorption spectrum of the transparent material can possess an absorption peak out of the B band and falls in the A band. In other embodiments, the absorption spectrum of the transparent material can possess an absorption peak neither in the B band nor in the A band.

Referring to FIG. 3, FIG. 3 shows a first illumination pattern 301 of a light emitting device package or light emitting apparatus according to some embodiments of the present disclosure and a second illumination pattern 303 of a light emitting device package or a light emitting apparatus without inert particles. The horizontal axis of FIG. 3 shows the light angle from 0 (defined propagation for the peak intensity) to 100 in two opposite directions, whereas the vertical axis shows the relative luminous intensity of the LED 130 at different angles. The first illumination pattern 301 is generated from a light emitting device package as shown in FIG. 1A and FIG. 1B, and the second illumination pattern 303 is generated from a light emitting device package without the inert particles 150A shown in FIG. 1A and FIG. 1B. As such, the first illumination pattern 301 resembles a Lambertian-like curve while the second illumination pattern 303 does not. A small dimple can be seen and a wide plateau can be identified in proximity to the 0 angle in the second illumination pattern 303.

Still referring to FIG. 3, the beam angle of the first illumination pattern 301 is about 60 degrees and thus the light angle is about 120 degrees. Compared to the second illumination pattern 303, the beam angle of which is approximately 80 degrees, resulting in a light angle of about 160 degrees. The definition of the beam angle and light angle are previously discussed and is not repeated here for simplicity. The incorporation of the inert particles in the encapsulant is evidenced to modify the illumination pattern of an LED in beam angle and uniformity.

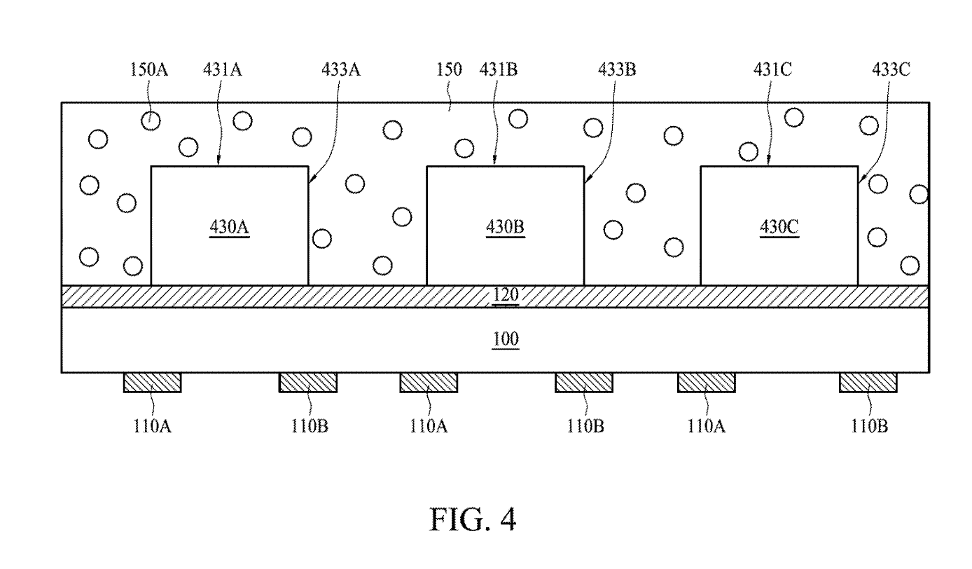

Referring to FIG. 4, FIG. 4 shows a cross sectional view of a light emitting apparatus containing more than one LEDs (430A, 430B, 430C). Numeral labels in FIG. 4 that are identical to those in FIGS. 1A and 1B are referred to the same element or its equivalent and are not repeated here for simplicity. Each of the LED possesses a top surface (431A, 431B, 431C), respectively, and a sidewall (433A, 433B, 433C), respectively. In some embodiments, the LED 430A emits the same color light as the LEDs 430B and 430C. In other embodiments, the LED 430A emits light with color different from that emitted from LEDs 430B and 430C. A light angle adjusting layer (150, 150A) covers the top surface (431A, 431B, 431C) and the sidewall (433A, 433B, 433C) of the LEDs (430A, 430B, 430C). In the embodiments where all LEDs (430A, 430B, 430C) emit same color, the inert particles 150A in the light angle adjusting layer are transparent to said color. In the embodiments where LEDs (430A, 430B, 430C) emit more than one color, the inert particles 150A in the light angle adjusting layer are transparent to said more than one color.

Referring to FIG. 1A, FIG. 1B, and FIG. 4, in some embodiments, the transparent inert particles 150A may include silicon, silica, silicon oxides, or the combinations thereof. However, the inert particles 150A are not limited to those materials consisting of elements such as silicon and oxygen. Other materials that are transparent to the light emitted from the encapsulated LED can be used as the inert particles 150A. An average diameter D of the inert particles 150A is preferably not close to half of the emission wavelength. In some embodiments where the emission light is blue, the average diameter D of the inert particles 150A is in a range of from about 0.5 μm to about 20 μm. In some embodiments, the binding agent or matrix 150 may include optical grade silicone-based materials or other viscous materials that is suitable to hold the inert particles 150A together.

In some embodiments, the refractive index (RI) of the inert particles 150A is different from that of the binding agent 150. In some embodiments, the RI of the inert particles 150 is about 0.15 lower than the RI of the binding agent 150. For example, the silicone-based binding agent possesses an RI of about 1.5, and the silica inert particle has an RI of about 1.4. In some embodiments, the loading of the inert particles 150A in the matrix 150 is in a range of from about 0.5 wt % to about 200 wt %. In some embodiments, the densities of the inert particles 150A and the matrix 150 are essentially similar. Hence in some embodiments, the weight percentage and volume percentage of the inert particles 150A in the matrix 150 are interchangeable. In some embodiments, for example, the weight percentage or the approximate volume percentage is measured by thermogravimetric analyzer (TGA). Silicon-based binding agent 150 may be removed through evaporation at a first predetermined temperature, leaving behind the inert particles and causing a weight loss to the complex (i.e., inert particles 150A and binding agent 150). In some embodiments, said first predetermined temperature is about 1000 degrees Celsius.

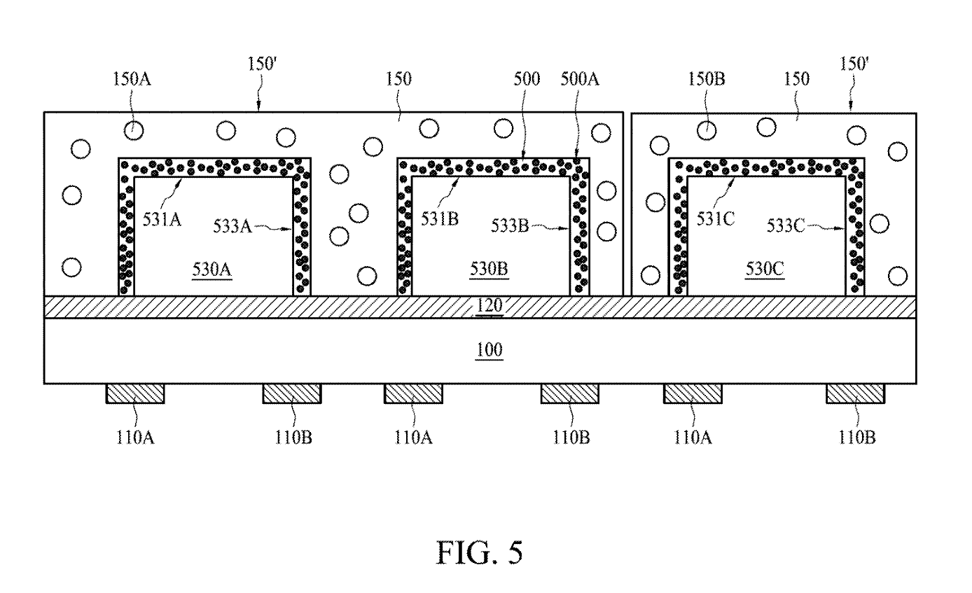

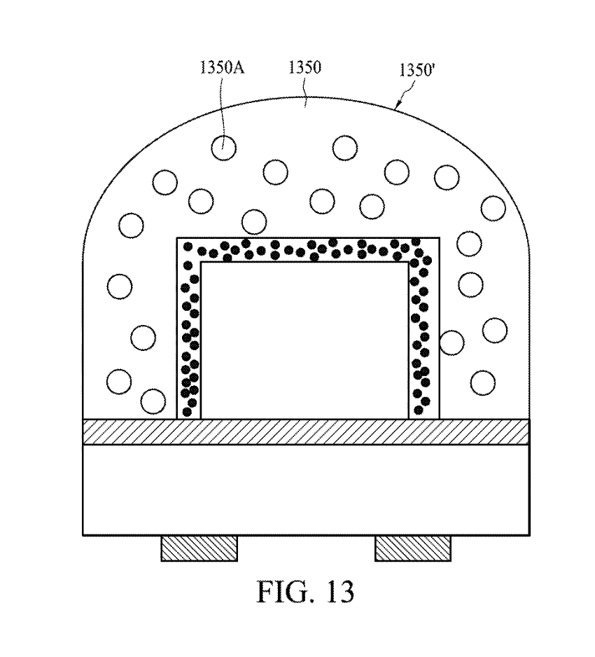

Referring to FIG. 5, FIG. 5 shows a cross sectional view of a light emitting apparatus containing more than one LEDs (530A, 530B, 530C). Numeral labels in FIG. 5 that are identical to those in FIG. 4 are referred to the same element or its equivalent and are not repeated here for simplicity. Each of the LED possesses a top surface (531A, 531B, 531C), respectively. In some embodiments, a top surface 150′ of the light angle adjusting layer (150, 150A) is configured to be essentially parallel to the top surfaces (531A, 531B, 531C) of the LEDs. In some embodiments, the aforesaid flat surface packaging of a narrow light angle LED can be utilized as a flash light source. However, the shape of the top surface 150′ is not limited to be flat. Other configurations for intended purposes can also be adopted such as those discussed in FIG. 13 to FIG. 15 in the present disclosure.

Still referring to FIG. 5, in some embodiments, the LED 530A emits the same color light as the LEDs 530B and 530C. In other embodiments, the LED 530A and 530B emit a first color different from a second color emitted from LED 530C. LEDs 530A and 530B emitting the first color are covered by a first light angel adjusting layer (150, 150A), and LED 530C emitting the second color is covered by a second light angel adjusting layer (150, 150B). The inert particles 150A in the first light angel adjusting layer are transparent to the first color and the inert particles 150B in the second light angel adjusting layer are transparent to the second color. Note in FIG. 5, a photo-conversion material layer (500, 500A) is disposed between the LEDs and the light angle adjusting layer (150, 150A). In some embodiments, the photo-conversion material layer (500, 500A) includes phosphor particles 500A and binding agent 500. The compositions of the binding agent 500 described herein can be referred to the binding agent 150 previously discussed in FIG. 1A, FIG. 1B, and FIG. 4. In other embodiments, the photo-conversion material layer (500, 500A) may include either phosphorescent materials and/or fluorescent materials. The photo-conversion material layer (500, 500A) is used to transform the color of the light emitted by LEDs (530A, 530B, 530C). In some embodiments, the photo-conversion material layer (500, 500A) contains yellow phosphor particles and can transform a blue light emitted by LEDs into a different wavelength light. In other embodiments, a dual phosphor may be used, which may contain yellow powder and red powder phosphor. By changing the material composition of the photo-conversion material layer (500, 500A), the desired light output color (e.g., a color resembling white) may be achieved. In some embodiments, the photo-conversion material layer (500, 500A) includes at least two sub-layers (not shown in FIG. 5). For example, one of these sub-layers may contain yellow phosphor particles mixed with binding agent, while the other one of these sub-layers may contain red phosphor particles mixed with binding agent.

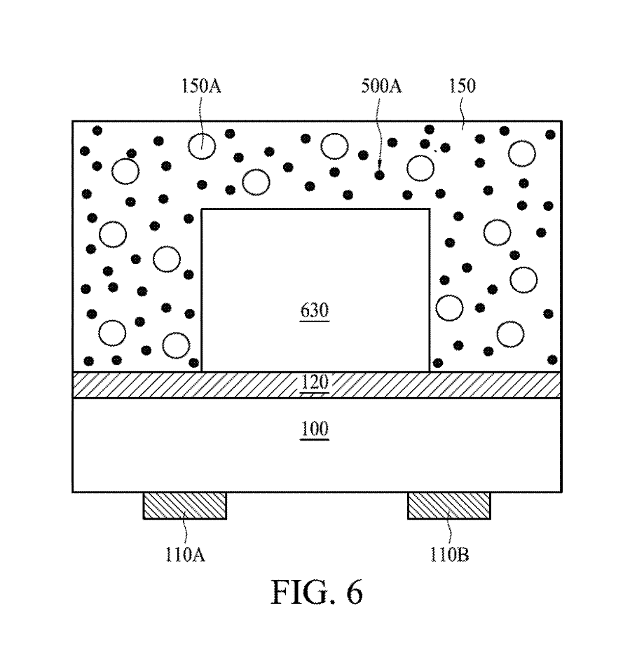

Referring to FIG. 6, FIG. 6 shows a cross sectional view of a light emitting device package. As shown in FIG. 6, the encapsulant (150, 150A) covering the LED 630 further includes photo-conversion material such as phosphor particles 500A. In other words, the phosphor particles 500A and the inert particles 150A are mixed in a same binding agent (matrix) 150. A difference between the inert particles 150A and the phosphor particles 500A is that inert particles 150 are not photo-sensitive and are configured not to chemically react with the light emitting from the LED 630, while the phosphor particles 500A are intended to absorb the energy of the emitted light of a first wavelength and release a portion of the energy in a form of a second wavelength. In addition, the inert particles 150A are transparent to the emitted light, whereas the phosphor particles 500A may not be transparent to the emitted light.

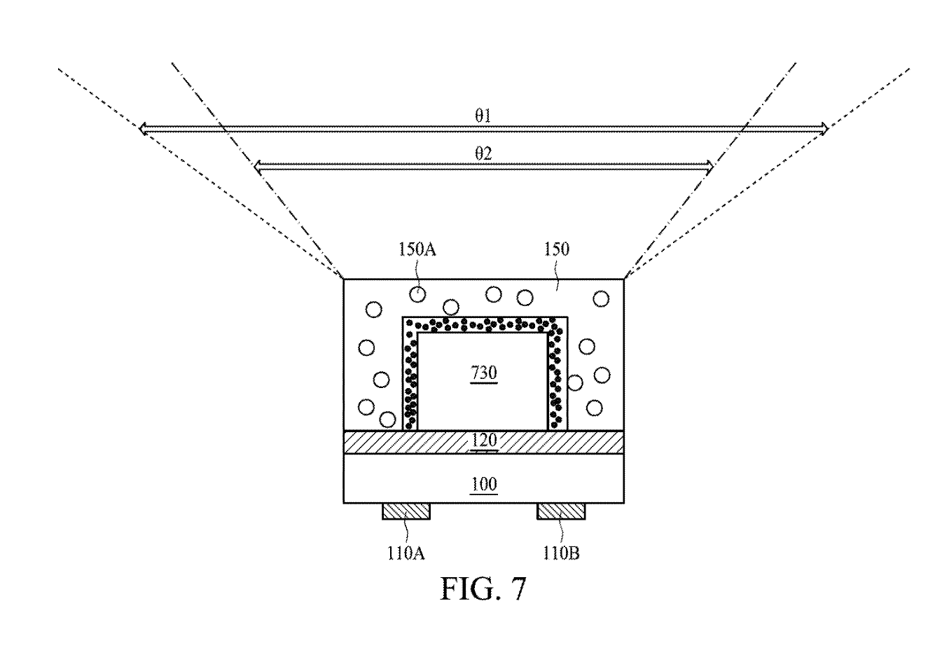

Referring to FIG. 7, FIG. 7 shows a cross sectional view of a light emitting device package. FIG. 7 is a singulated LED 730 package encapsulated by a light angle adjusting layer (150, 150A). The light angle θ1 denoted in FIG. 7 is referred to a light emitting device package without the transparent inert particles 150A. In some embodiments such as a flip chip LED, light angle θ1 is from about 160 to about 180 degrees. On the other hand, the light angle θ2 denoted in FIG. 7 is referred to a light emitting device package with the transparent inert particles 150A, in accordance with some embodiments of the present disclosure. In some embodiments, light angle θ2 is about 120 degrees or below. The luminous efficacy of the light emitting device package with or without inert particles 150A are essentially identical. In other words, the incorporation of the inert particles 150A does not generate measurable output loss.

FIG. 8A and FIG. 8B show cross sectional views of a flip chip light emitting apparatus. The flip chip LED as 830A as shown in FIG. 8A includes a p-doped semiconductor layer 831, a n-doped semiconductor layer 833, and a light emitting layer 835 such as an MQW structure between the two doped semiconductor layers. One contact 110A′ is connected to the p-doped semiconductor layer 831, and the other contact 110B′ is connected to the n-doped semiconductor layer 833. The two contacts 110A′ and 110B′ are further coupled to the conductive terminals 110A and 110B on a surface of the substrate 100 opposite to the surface receiving the flip chip LED 830A. Similarly, in FIG. 8B, the flip chip LED 830B is covered with a photo-conversion material layer (500, 500A) containing, for example, phosphor particles 500A and binding agent 500. As known in the art that the flip chip LED emit a greater light angle than the vertical LED, and hence preventing the flip chip configuration from directional lighting applications such as flash light sources or back light modules. The present disclosure provides that adding suitable amount of the transparent, inert particles 150A in the encapsulant (150, 150A), for example, a weight percentage of from about 0.5 wt % to about 200 wt %, the light angle can be narrowed down to 120 degrees or below without compromising output intensity.

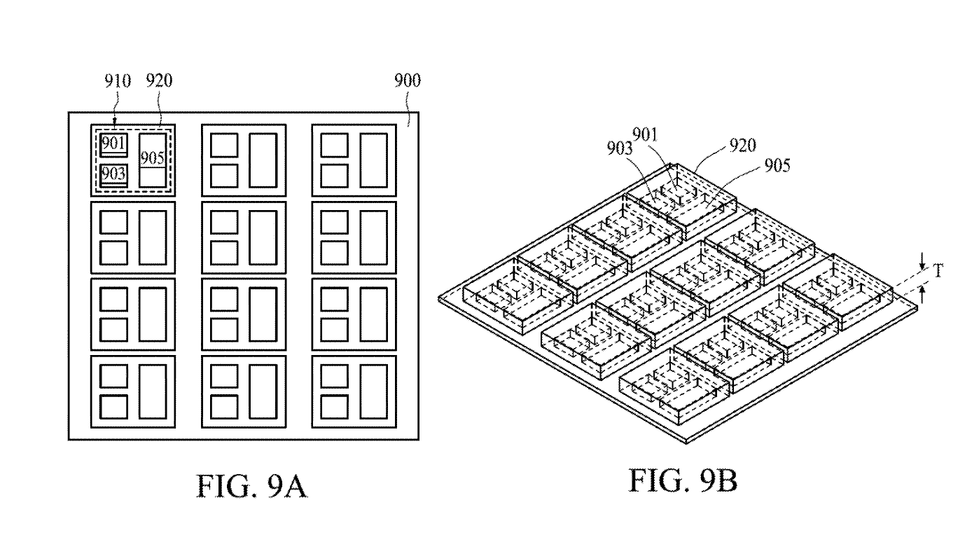

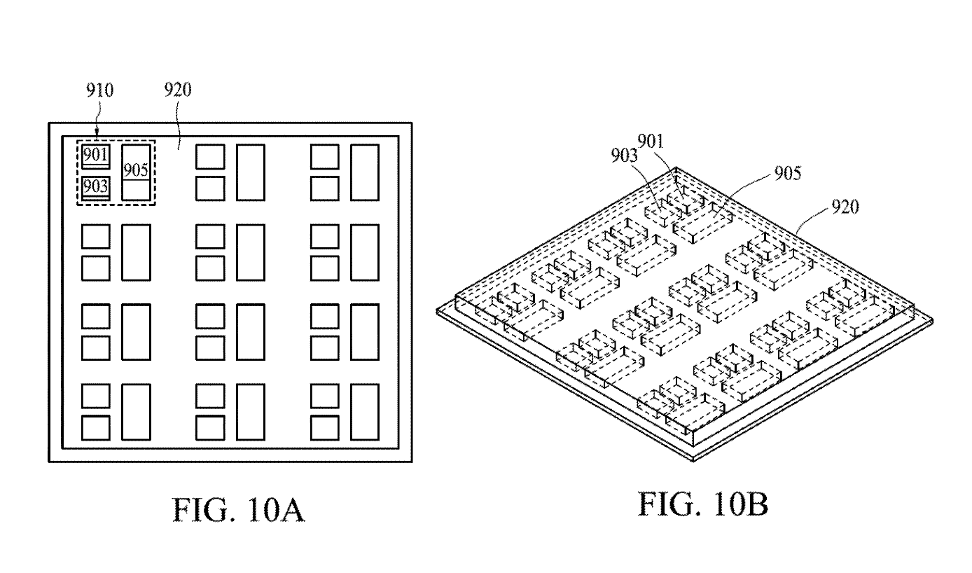

In some embodiments, the light emitting apparatus is a red-green-blue (RGB) LED back light module as shown in FIGS. 9A, 9B, 10A, 10B. In FIG. 9A, an RGB LED unit 910 is arranged in an array fashion on a carrier substrate 900. For example, LED 901 emits red light, LED 903 emits blue light, and LED 905 emits green light. However, it is understood that the arrangement of the LEDs of different colors is design choice and may be dependent on a particular application or use. Each of the RGB LED unit 910 is encapsulated in a light angle adjusting layer 920 covering top surfaces and sidewalls of the LEDs 901, 903, 905. As discussed previously, the light angel adjusting layer 920 not only protect the bare LEDs from the environment but also alter the light angle of the LEDs. FIG. 9B is a perspective view of the RGB backlight module shown in FIG. 9A. A thickness T of the light angle adjusting layer 920 is greater than the thicknesses of the LEDs 901, 903, 905. The inert particles (not shown in FIG. 9A and FIG. 9B) in the light angle adjusting layer 920 are transparent to red, blue, and green colors. Alternatively, in other embodiments as shown in FIG. 10A and FIG. 10B, several or all of the RGB LED units 910 are encapsulated in a light angle adjusting layer 920. In other embodiments, LEDs emitting different colors are encapsulated in different light angle adjusting layers. For example, a red LED is covered by a first light angle adjusting layer which contains inert particles transparent to red color, whereas a blue LED is covered by a second light angle adjusting layer which contains inert particles transparent to blue color. The loading or weight percentage of the inert particles in the first and the second light angle adjusting layers can be essentially identical or different. The compositions of the inert particles in the first and the second light angle adjusting layers may be essentially identical or different.

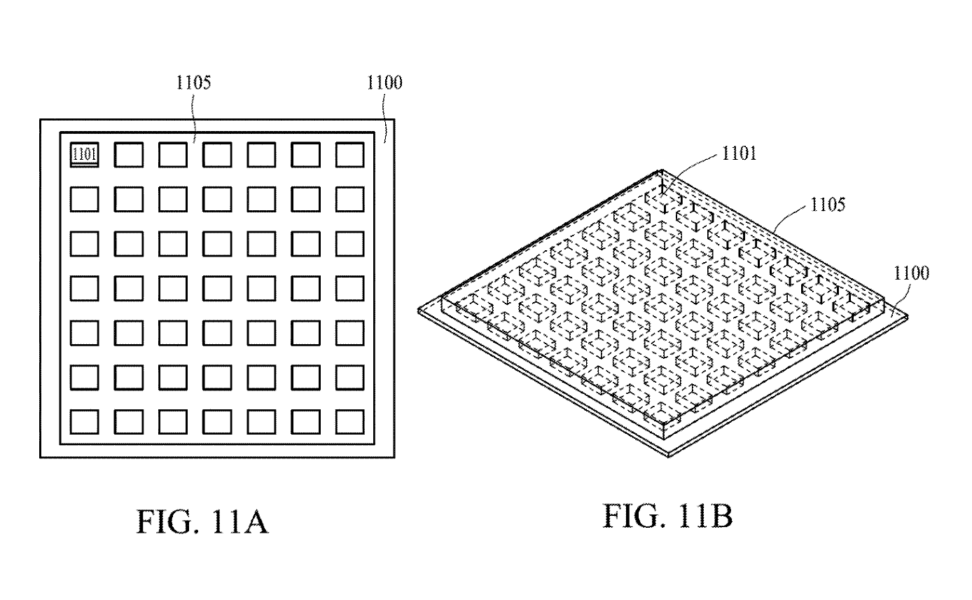

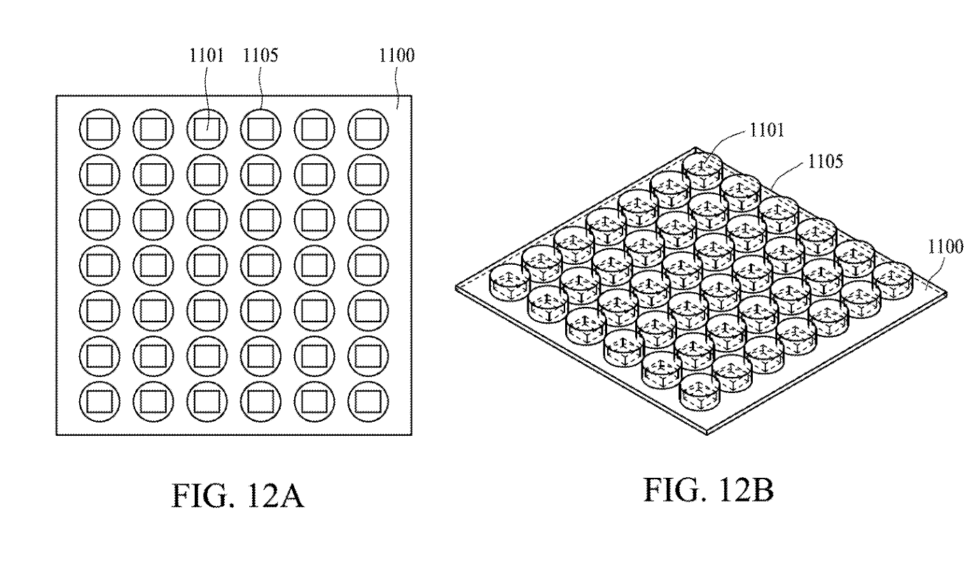

In some embodiments, the light emitting apparatus is a white LED back light module as shown in FIGS. 11A, 11B, 12A, 12B. As shown in FIGS. 11A and 11B, for example, the LED 1101 emits blue light, and the light angle adjusting layer 1105 includes not only broad spectrum yellow phosphor particles, but also inert particles transparent to blue light and yellow light, to result in emission of white light. In some embodiments, the light angle adjusting layer 1105 can be a continuous encapsulant covering several or all of the LEDs 1101 on the carrier substrate 1100, as shown in FIGS. 11A and 11B. In other embodiments, the light angle adjusting layer 1105 can be discrete encapsulants covering one LED 1101 on the carrier substrate 1100, as shown in FIGS. 12A and 12B. The shape of the discrete encapsulant can be different from that of the LED. For example, the LED is a tetragonal shape, and the discrete encapsulant is a circular shape.

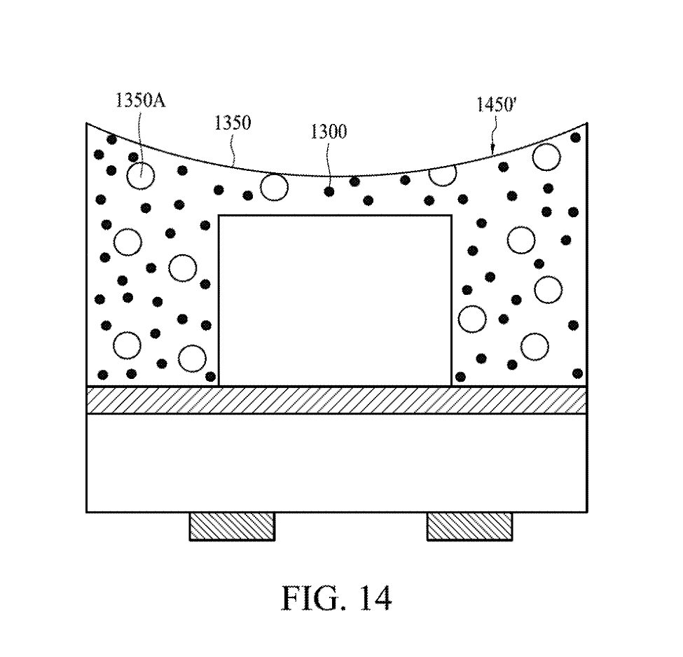

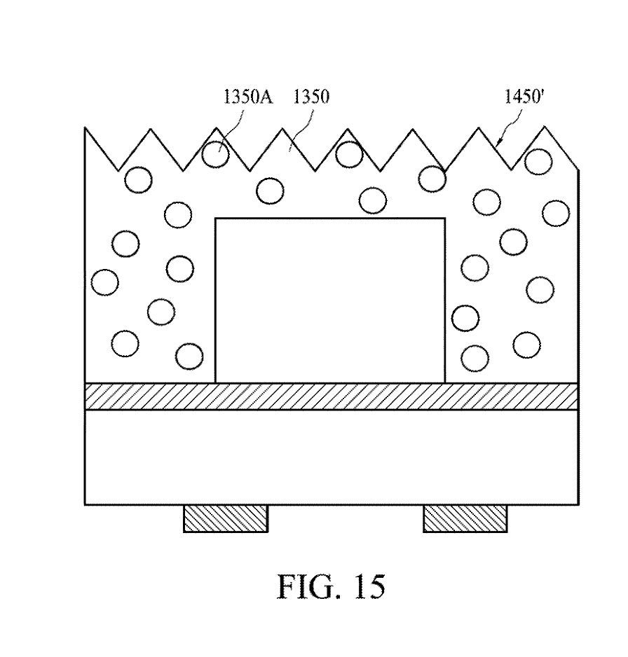

Referring to FIG. 13, FIG. 14, and FIG. 15, a top surface of the light angle adjusting layer can possess different shapes for intended purposes such as further light directional adjustment or light extraction enhancement. In some embodiments, the top surface 1350′ of the light angle adjusting layer (1350, 1350A) is a convex or a hemispherical shape as shown in FIG. 13. The specific value of the curvature is a design choice and/or may be dependent on a particular application or use. In some embodiments, the top surface 1450′ of the light angle adjusting layer (1350, 1350A) is a concave shape as shown in FIG. 14. In some embodiments, the top surface 1550′ of the light angle adjusting layer (1350, 1350A) is a saw-tooth shape as shown in FIG. 15. Each of the surface configurations shown in FIG. 13 to FIG. 15 may further include a textured surface to enhance light scattering. Referring back to FIG. 9A to FIG. 12B, the top surface of the light angle adjusting layer can be any of the shape presented in FIGS. 13-15 or the combinations thereof.

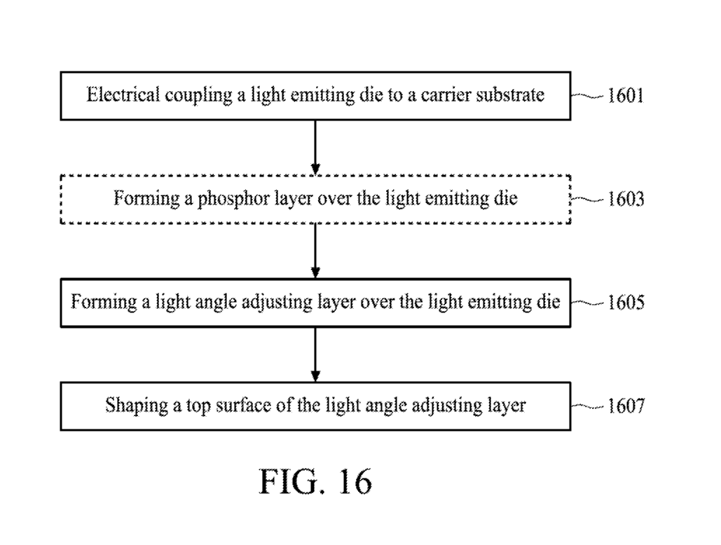

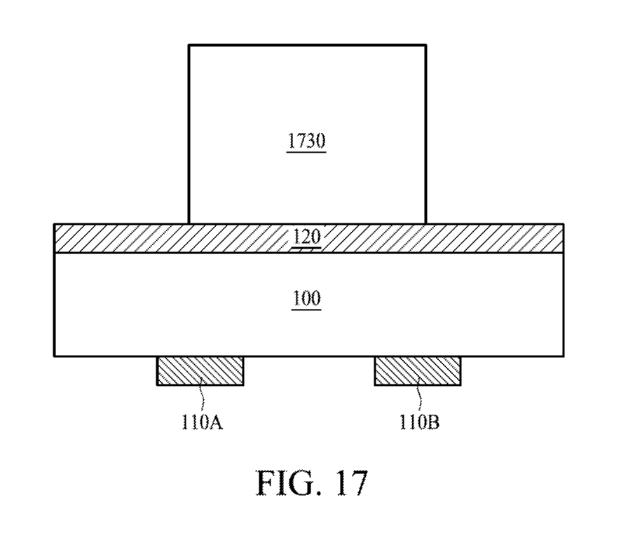

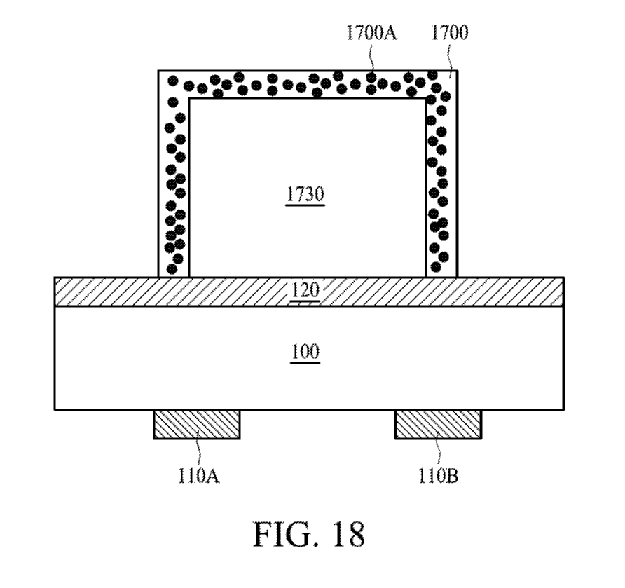

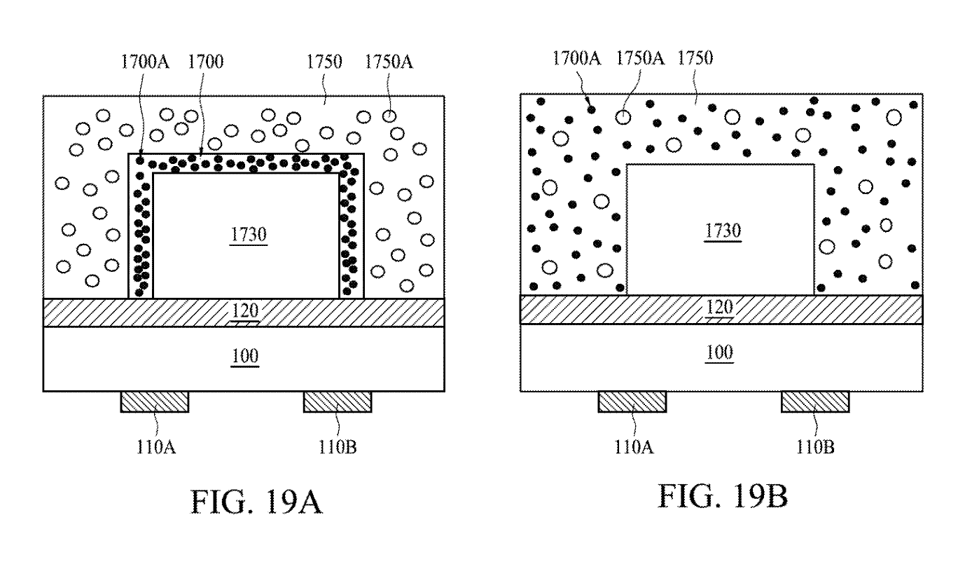

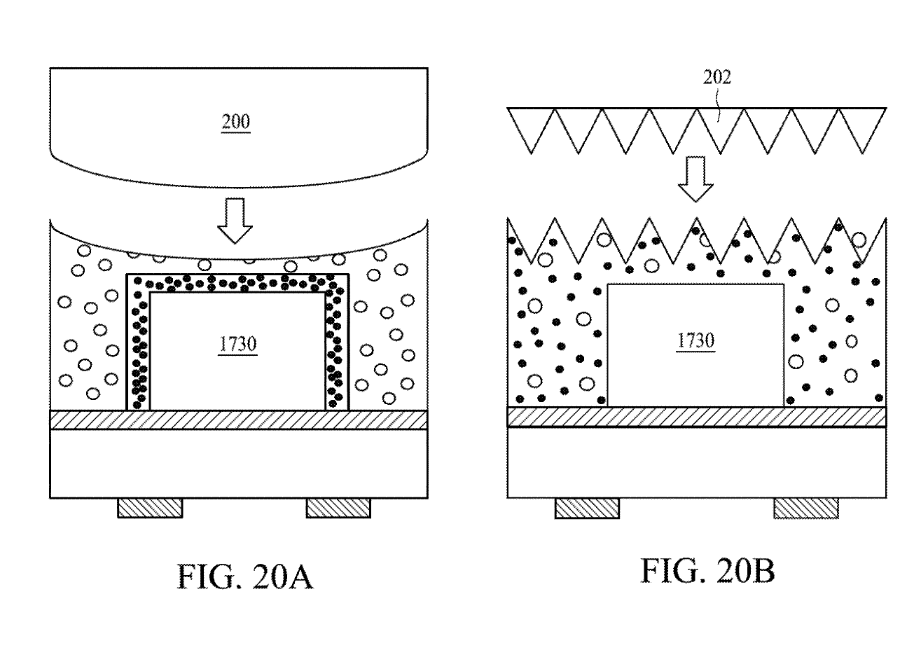

FIG. 16 shows several operations of a method for manufacturing a light emitting device or a light emitting apparatus in the present disclosure. Operation 1601 is further illustrated in FIG. 17. An LED 1730 is disposed over a carrier substrate 100. The p-doped semiconductor layer and n-doped semiconductor layers of the LED 1730 are electrically coupled to external terminals 110A, 110B, respectively. In some embodiments the LED 1730 is a flip chip LED with a p-doped semiconductor layer (not shown) in proximity to a top surface of the carrier substrate 100. Optional operation 1603 is further illustrated in FIG. 18. A photo-conversion material layer (1700, 1700A) containing phosphor particles 1700A and binding agent 1700 is disposed to cover a top surface and a sidewall of the LED 1730.

Operation 1605 is further illustrated in FIGS. 19A and 19B. In FIG. 19A, a light angle adjusting layer (1750, 1750A) containing inert particles 1750A and binding agent 1750 is subsequently formed over the photo-conversion material layer (1700, 1700A) as shown in FIG. 18. However, when the operation 1603 is omitted, the phosphor particles 1700A can be mixed into the binding agent 1700 together with the inert particles 1750A, as shown in FIG. 19B. The inert particles 1750A to be mixed are previously discussed in the present disclosure. The inert particles 1750A, or inert fillers, may possess a refractive index at least 0.15 lower than the refractive index of the binding agent 1750. The inert particles 1750A may possess a diameter of from about 0.5 μm to about 20 μm. In some embodiments, no phosphor particle 1700A is mixed into the binding agent. Operation 1607 is further illustrated in FIGS. 20A and 20B. In FIG. 20A, a molding stencil 200 having a convex shape is pressed toward a top surface of the light angle adjusting layer (1750, 1750A). After a curing operation, the top surface of the light angle adjusting layer (1750, 1750A) exhibits a concave profile. Similarly, in FIG. 20B, as a result of being shaped by the saw-tooth shape molding stencil 202 and being cured, a top surface of the light angle adjusting layer (1750, 1750A) exhibits a saw-tooth profile. Furthermore, the top surface of the light angle adjusting layer (1750, 1750A) can be shaped as a flat profile that is parallel to the top surface 531C of the LED 530C, as previously shown in FIG. 5.

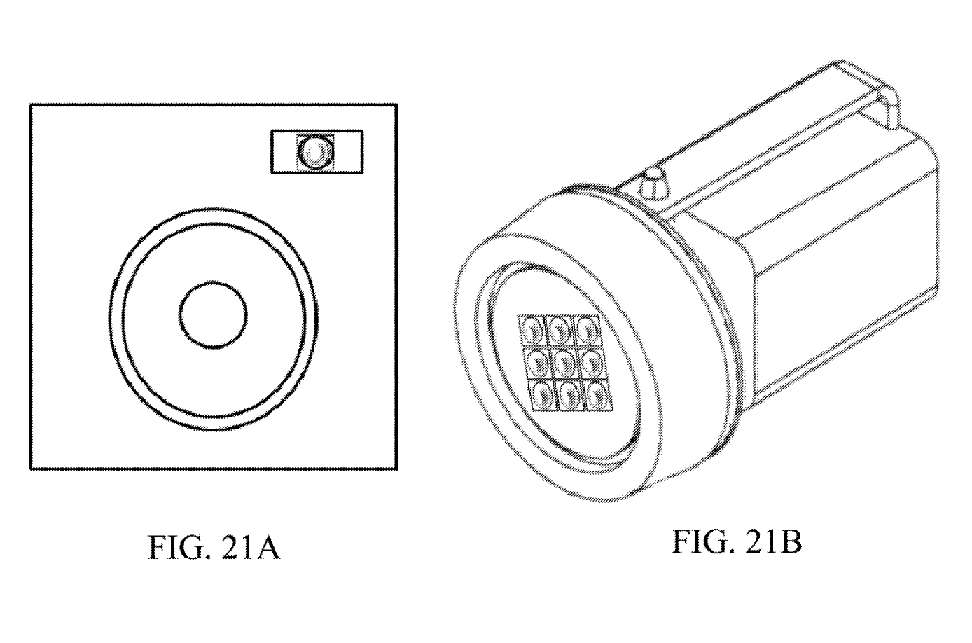

Referring to FIG. 21A and FIG. 21B, flash light applications such as camera flash light (FIG. 21A) and a hand-held flash light (FIG. 21B) using the light emitting device or the light emitting apparatus described herein are illustrated. Other applications which require narrow light angle (e.g. narrower than 120 degrees) with a flat LED package top surface profile, good light output intensity, and uniform illumination profile, are suitable to adopt the light emitting apparatus described in the present disclosure.

Some embodiments of the present disclosure provide a light emitting device package, including a light emitting die emitting a first color and an encapsulant encapsulating the light emitting die. The encapsulant includes a matrix and a plurality of inert particles dispersed in the matrix. The inert particles are transparent to the first color, and a radiation pattern of the light emitting package is lambertian-like.

In some embodiments, the light emitting device package further includes a phosphor layer between the light emitting die and the encapsulant.

In some embodiments, a weight percent of the inert particles in the matrix is in a range of from about 0.5 wt % to about 200 wt %.

In some embodiments, a refractive index difference between the inert particles and the matrix is lower than about 0.15.

In some embodiments, the inert particles include silicon, silica, silicon oxides, or the combinations thereof.

In some embodiments, a diameter of the inert particle is in a range of from about 0.5 μm to about 20 μm.

In some embodiments, a surface of the encapsulant is parallel to a top surface of the light emitting die.

In some embodiments, the encapsulant further includes phosphor particles dispersed in the matrix.

Some embodiments of the present disclosure provide a light emitting apparatus, including a first light emitting die emitting a first color, having a top surface and a sidewall, and a first light angle adjusting layer covering the top surface and the sidewall of the light emitting die. The first light angle adjusting layer includes a plurality of particles transparent to the first color and a matrix holding the plurality of particles.

In some embodiments, the particles are composed of the elements consisting essentially of silicon and oxygen.

In some embodiments, the particles are evenly dispersed in the matrix, configured to adjust a light angle of the light emitting apparatus to be essentially or lower than about 120 degrees.

In some embodiments, the light emitting apparatus is a flash light source.

In some embodiments, the light emitting apparatus is a back light module.

In some embodiments, the first light emitting die is a flip chip light emitting diode (LED).

In some embodiments, the light emitting apparatus further includes a second light emitting die emitting a second color, having a top surface and a sidewall, and a second light angle adjusting layer covering the top surface and the sidewall of the light emitting die. The second light angle adjusting layer includes a plurality of particles transparent to the second color and a matrix holding the plurality of particles.

Some embodiments of the present disclosure provide a method for manufacturing a light emitting device emitting a lambertian-like radiation pattern. The method includes (i) electrical coupling a light emitting die to a carrier substrate; (ii) forming a light angle adjusting layer over the light emitting die, wherein the light angle adjusting layer comprises a plurality of inert fillers transparent to a wavelength emitting by the light emitting die; and (iii) shaping a top surface of the light angle adjusting layer.

In some embodiments, the forming the light angle adjusting layer of the method include (i) providing the inert fillers having a diameter of from about 0.5 μm to about 20 μm, a difference of a refractive index of the fillers and a matrix holding the fillers being below 0.15; and (ii) mixing about 0.5 wt % to about 200 wt % of the fillers into the matrix.

In some embodiments, the shaping the top surface of the light angle adjusting layer of the method includes shaping the top surface to become a flat, convex, concave, or a saw-tooth shape.

In some embodiments, the method further includes forming a phosphor layer over the light emitting die.

In some embodiments, the forming the light angle adjusting layer of the method further includes mixing phosphor particles into the matrix.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A light emitting device package, comprising:
a light emitting die emitting a first color;
an encapsulant encapsulating the light emitting die, comprising:
a matrix;
a plurality of inert particles dispersed in the matrix,
wherein the inert particles are transparent to the first color, and a radiation pattern of the light emitting device package is Lambertian-like.

2. The light emitting device package of claim 1, further comprising a phosphor layer between the light emitting die and the encapsulant.

3. The light emitting device package of claim 1, wherein a weight percent of the inert particles in the matrix is in a range of from about 0.5 wt % to about 200 wt %.

4. The light emitting device package of claim 1, wherein a refractive index difference between the inert particles and the matrix is lower than about 0.15.

5. The light emitting device package of claim 1, wherein the inert particles comprises silicon, silica, silicon oxides, or the combinations thereof.

6. The light emitting device package of claim 1, wherein a diameter of the inert particle is in a range of from about 0.5 μm to about 20 μm.

7. The light emitting device package of claim 1, wherein a surface of the encapsulant is parallel to a top surface of the light emitting die.

8. The light emitting device package of claim 1, wherein the encapsulant further comprising phosphor particles dispersed in the matrix.

9. A light emitting apparatus, comprising:
a first light emitting die emitting a first color, having a top surface and a sidewall;
a first light angle adjusting layer covering the top surface and the sidewall of the light emitting die, the first light angle adjusting layer comprising:
a plurality of particles transparent to the first color; and
a matrix holding the plurality of particles.

10. The light emitting apparatus of claim 9, wherein the particles are composed of the elements consisting essentially of silicon and oxygen.

11. The light emitting apparatus of claim 9, wherein the particles are evenly dispersed in the matrix, configured to adjust a light angle of the light emitting apparatus to be essentially or lower than about 120 degrees.

12. The light emitting apparatus of claim 9, wherein the light emitting apparatus is a flash light source.

13. The light emitting apparatus of claim 9, wherein the light emitting apparatus is a back light module.

14. The light emitting apparatus of claim 9, wherein the first light emitting die is a flip chip light emitting diode (LED).

15. The light emitting apparatus of claim 9, further comprising:
a second light emitting die emitting a second color, having a top surface and a sidewall;
a second light angle adjusting layer covering the top surface and the sidewall of the light emitting die, the second light angle adjusting layer comprising:
a plurality of particles transparent to the second color; and
a matrix holding the plurality of particles.

16. A method for manufacturing a light emitting device emitting a Lambertian-like radiation pattern, the method comprising:
electrical coupling a light emitting die to a carrier substrate;
forming a light angle adjusting layer over the light emitting die, wherein the light angle adjusting layer comprises a plurality of inert fillers transparent to a wavelength emitting by the light emitting die; and
shaping a top surface of the light angle adjusting layer.

17. The method of claim 16, wherein the forming the light angle adjusting layer comprises:
providing the inert fillers having a diameter of from about 0.5 μm to about 20 μm, a difference of a refractive index of the fillers and a matrix holding the fillers being below 0.15; and
mixing about 0.5 wt % to about 200 wt % of the fillers into the matrix.

18. The method of claim 16, wherein the shaping the top surface of the light angle adjusting layer comprises shaping the top surface to become a flat, convex, concave, or a saw-tooth shape.

19. The method of claim 16, further comprising forming a phosphor layer over the light emitting die.

20. The method of claim 17, wherein the forming the light angle adjusting layer further comprises:
mixing phosphor particles into the matrix.
